(19) United States
(12) Patent Application Publication
(10) Pub. No.: US 2025/0392159 A1
(43) Pub. Date: Dec. 25, 2025

(54) Systems for and Methods of Enabling Proactive Maintenance with Advanced Power Quality Monitoring

(71) Applicant: Power Survey and Equipment Limited (dba Powerside), Saint-Laurent (CA)

(72) Inventors: Nicolas Seishin Nakamura, New Lenox, IL (US); Louis Marchand, Montreal (CA); Stephane Do, Alameda, CA (US); Mahdi Mankai, Pointe-Claire (CA); Luis Ricardo Vega, Glen Allen, VA (US); Kamron Tangney, Murrieta, CA (US)

(21) Appl. No.: 19/204,132

(22) Filed: May 9, 2025

Related U.S. Application Data
(60) Provisional application No. 63/645,826, filed on May 10, 2024.
(60) Provisional application No. 63/716,544, filed on Nov. 5, 2024.

(51) Int. Cl. H02J 13/00; H02J 3/00

(52) U.S. Cl. CPC H02J 13/00002; H02J 3/0012; H02J 2203/20; H02J 2300/22

(57) ABSTRACT

Systems and methods are directed to increasing the reliability and resilience of power grids, solar farms, and other energy sources, by predicting fault events before they occur and taking preventive action, thus avoiding system down time. In accordance with embodiments, a method of responding to pre-fault events in an electrical system includes monitoring electrical signals generated by the system; comparing the electrical signals to fault signatures; in response to the comparison, triggering a maintenance event, such as dispatching maintenance personnel, automatically disconnecting a component predicted to fail within a pre-determined time limit, or powering down the system, to name only a few examples. The fault signatures can be generated using artificial intelligence.

### RELATED APPLICATION(S)

This application claims priority under 35 U.S.C. § 119 (e) of the co-pending U.S. Provisional Patent Application Ser. No. 63/645,826, filed May 10, 2024, and titled “Systems for and Methods of Enabling Proactive Maintenance with Advanced Power Quality Monitoring,” and Ser. No. 63/716,544, filed Nov. 5, 2024, and titled “Empowering a Proactive Grid with Power Quality Visibility,” both of which are hereby incorporated by reference in their entireties.

### FIELD OF THE INVENTION

This invention is directed to electrical systems, such as power grids and solar farms. More particularly, this invention is directed to monitoring these systems to anticipate fluctuations or failures in them and to service them before these fluctuations or failures occur, or to reduce the likelihood of these fluctuations or failures.

### BACKGROUND OF THE INVENTION

Often, electrical systems fail with little notice, leaving personnel unprepared to repair these systems in a timely manner while replaced parts are ordered and repair crews dispatched. One alternative is to keep multiple system parts on hand and repair crews on stand-by, neither alternative being feasible for large-scale, widely dispersed, and costly equipment.

The evolution of these systems (for simplicity, referred to generally a “grids”) is progressively shifting towards a much more dynamic and complex system. This is especially true as these grids age and evolve. Grids that are more decentralized and reliant on inverter-based technologies, plus increasing demand for electrification of new types of loads, are introducing more challenges to grid stability. Grid operators must adapt, requiring more extensive, granular, and timely data to enable analytics for improved efficiency and development of proactive mitigation strategies.

For example, maintaining grid reliability during blue sky days and resiliency during black sky days is relevant now more than ever in the rapidly changing grid. Moving from a reactive operation to a proactive operation is a key initiative in maintaining and improving grid reliability for grid operators.

Thus, there is a need to predict system failures, before they occur, allowing for preventive maintenance, component replacement, and other preventive actions.

### BRIEF SUMMARY OF THE INVENTION

In accordance with the embodiments, advanced power quality monitoring provides critical visibility into the health of a power system, providing grid operators with actionable information that enables improving grid resilience. In some embodiments, power quality monitors (also referred to as power quality analyzers) equipped to monitor, alarm, and provide compliance reporting on disturbances can provide early warning notifications on potential system faults or equipment failure before they develop into permanently faulted conditions that result in costly system outages and downtime. In some embodiments, power quality monitors or other systems are able to automatically switch out mal-functioning or soon-to-malfunction equipment to avoid grid downtime. In some embodiments, this failure determination is made by comparing real-time voltage values and patterns, real-time current values and patterns, or both with corresponding fault signatures or IEEE standards, such that a range of pre-determined differences signal that a particular component in the grid is malfunctioning, will fail soon within a predicted time, or has already failed, to name only a few examples.

In a first aspect, a method of responding to pre-fault events in an electrical system includes monitoring electrical signals generated by the system; comparing the electrical signals to fault signatures; and in response to the comparison, triggering a maintenance event. In some embodiments, the electrical signals correspond to fault signatures, thereby indicating a pre-fault condition. In some embodiments, the fault signatures include a magnitude of a signal, a frequency of the signal, a phase angle of the signal, patterns of the magnitude, phase angle and frequencies, a time period over which the signals occur, or any combination thereof. In some embodiments, the method further includes generating a database correlating signatures with components and predicted times to failure. In some embodiments, the correlations in the database are generated using artificial intelligence, dynamic modeling, machine learning, or any combination thereof.

In some embodiments, the maintenance event includes automatically or manually disconnecting a component associated with the signal. In some embodiments, the maintenance event includes automatically or manually powering down the system. In some embodiments, the maintenance event includes sending an alert to a predetermined party or location, to log the fault, to manually perform a maintenance event, or to generate a report correlating the electrical signal to a fault, to name only a few examples.

In some embodiments, the signature corresponds to a high-frequency impulse within a predetermined range. In some embodiments, the monitoring is performed using a power quality monitor. In some embodiments, monitoring electrical signals includes sampling the signals at 1 MHz or higher frequencies.

In a second aspect, a system for maintaining a power source includes an analyzer to analyze one or more signals of the power source; a comparator for comparing the one or more signals to a fault signature correlating a failure of a component of the power source to a predicted time to failure; and a maintenance module for generating a maintenance event when the signals correspond to the fault signature. In some embodiments, the analyzer is coupled to the comparator, the maintenance module, or both over a network, such as the Internet or a Cloud network.

In some embodiments, the maintenance module generates the maintenance event in real time. In some embodiments, the analyzer includes a power quality monitor. In some embodiments, the system is included in a power quality monitor.

### BRIEF DESCRIPTION OF THE DRAWINGS

The figures are provided merely for the illustration of some embodiments and do not limit the invention in any way. Similar labels refer to the same or similar elements.

FIGS. 1-3 are graphs plotting high-frequency impulse pre-fault events over time, with clusters of pre-fault events indicating likely catastrophic failures, prompting pro-active maintenance, in accordance with some embodiments.

FIG. 4 illustrates a pre-faults event table correlating pre-fault signatures with catastrophic faults, components, locations of the components, a “real potential fault” flag, and predicted times to failure, in accordance with some embodiments.

FIG. 5 is a flow chart of steps for monitoring pre-fault events and taking pro-active maintenance, in accordance with some embodiments.

FIG. 6 is a block diagram of elements for monitoring a component, in accordance with some embodiments.

FIG. 7 shows the elements of a system used to illustrate detecting high order harmonic disturbances and take preventive action, in accordance with some embodiments.

FIG. 8 is a Voltage Harmonics Compliance Chart used to identify harmonics disturbances in the system in FIG. 8, in accordance with some embodiments.

FIGS. 9 and 10 are Conducted Emissions Heat Maps for the system in FIG. 8, used to identify harmonic distortions or high frequency emission disturbances in the system in FIG. 7, in accordance with some embodiments.

FIG. 11 is shows a system used to detect imbalance at a Net Metering Application, to illustrate pre-fault signatures in accordance with some embodiments.

FIGS. 12A-D are graphs showing overloading on the neutral and high zero sequence current imbalance, to illustrate pre-fault signatures in accordance with some embodiments.

### DETAILED DESCRIPTION OF THE EMBODIMENTS

Monitoring power quality provides critical insights into the health of electrical systems, such as power grids and solar farms, serving end users with actionable information that enables improvements to system reliability and resiliency.

Power quality is defined as the influence that voltage and current anomalies have on end-use equipment. Good power quality enables an optimal level of electrical health, providing assurance for operational stability and equipment efficiency. In contrast, poor power quality occurs when a disturbance interferes with the normal operation of equipment or the electrical system and involves deviations from a generated sine wave at the fundamental frequency. Disturbances such as voltage sags, voltage swells, harmonics, high frequency transients, and imbalance are examples of poor power quality. Examples below illustrate some effects these power quality issues can have on equipment and systems.

“Power metering” and “power quality monitoring” are often used interchangeably. However, they are different in nature regarding the granularity of measurements, alarms, and compliance with the respective industry standards. Power quality monitors provide high fidelity information that allows the user to uncover issues that often go unseen by traditional power metering systems. Typically, power quality monitors adhere to an international standard on how the measurements are taken, the most common being Electromagnetic Compatibility (EMC)—Part 4-30: Testing and Measurement Techniques-Power Quality Measurement Methods,” in IEC 61000-4-30:2015 Ed3, 2015. (IEC 61000-4-30 Ed3).

Utilities typically install power quality monitors to provide visibility and data on grid conditions without having to physically be on-site to collect the measurements.

Historically, these have been installed at feeder sources or substations, but have recently been extended downline to critical customers (e.g., data centers, hospitals, renewable energy sites, etc.), generation sites, and grid edge locations. Power quality monitoring is becoming more common for compliance verification (e.g., “IEEE Recommended Practice for Monitoring Electric Power Quality,” IEEE Std 1159-2019, 13 Jun. 2019 and IEEE 519-2022 for harmonic control in electrical power systems; and, in Europe, Norm EN 50160 on Power Quality Compliance Verification).

In accordance with some embodiments, power quality monitors are coupled to a communications network (either intranet or via a 4G/5G cellular modem) to provide remote access and enable real-time grid condition monitoring. This enhanced visibility saves time with diagnosing grid issues, the detection of changing trends (e.g., harmonics increasing over time), and overall grid design limitations.

From this visibility, utilities are able to see baseline conditions, allowing them to set notifications for when the system is performing outside of normal operating conditions. This is often brought to the attention of someone familiar with power quality issues, typically Power Quality Engineers, who can then decide whether further action is required.

For larger system deployments, attempting to routinely inspect each power quality monitoring site for potential issues is very time consuming. Thus, in accordance with some embodiments that automatically analyze and generate event notifications, Power Quality Engineers are able to effectively utilize their time by focusing on critical issues and events, rather than manually filtering through data.

In accordance with some embodiments, a power quality monitor, such as the PQube®3 power quality analyzer, from Powerside, Alameda, California, USA, provides fault alarming on highly granular data, honing into problematic nuances in the electrical signal. These incipient electric disturbances can provide early warning notifications on potential system faults and equipment failure before developing into a permanently faulted condition, resulting in costly system outages and downtime. In some embodiments, proactive action can be taken automatically, such as by switching a first component with a predicted time to failure within a pre-determined window (indicating impending failure) with a second, replacement (back-up) component. In some embodiments, if a predicted failure of a component is able to be averted or delayed by tuning/adjusting one or more operating values of the component (e.g., voltage value, characteristics of a switching frequency, such as harmonics, etc.), the one or more values are adjusted to eliminate the predicted failure or increase the time to failure. Other actions that can be taken in accordance with embodiments include compliance verification, event frequency tracking, and monitoring sustained power quality issues (e.g., voltage imbalance is sustained above 3% for a predetermined amount of time), to name only a few examples.

These proactive actions can be triggered directly at the electrical system or over a network, such as the Internet or the Cloud, from a remote site. In addition, reports can be generated for Power Quality Engineers and other personnel to study the functioning of the electrical systems (e.g., historical data).

In some embodiments, power characteristics defining a “fault signature” or other anomaly are determined. For example, when analyzing a component fault, analysis may determine that 1 week before the failure, the utility voltage had a rapid sequence of spikes at a particular frequency. The system associates this fault signature with the failure, such that detecting a similar fault signature in the future (on the same or different system) will generate an event alarm, which in turn triggers proactive solutions, such as component replacement. In some embodiments, this association between fault signatures and actions is determined by artificial intelligence or machine learning, to name only a few examples, that use the historical data to make the correlations.

One example of a highly granular event alarm that can detect these anomalies is high frequency (HF) impulse. This measurement has characteristics with sensitive sub-cycle event triggers that can be leveraged for predictive analysis and proactive maintenance. The HF impulse alarming condition is a transient capture that samples the waveform up to 4 MHz (single voltage channel, 250 ns resolution) or 1 MHz (4 voltage channels, 1 us resolution). This high sampling rate enables detection of voltage anomalies in the electrical system that are typically invisible to traditional monitoring equipment. These frequencies and resolutions are merely exemplary and do not limit the scope of the invention. After reading this disclosure, those skilled in the art will recognize other frequencies and resolutions that can also be used in accordance with the embodiments.

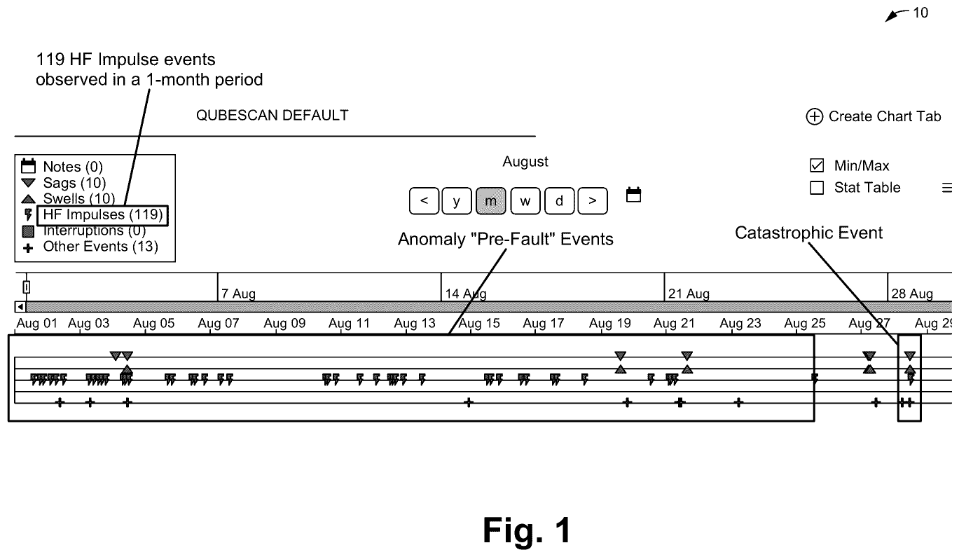

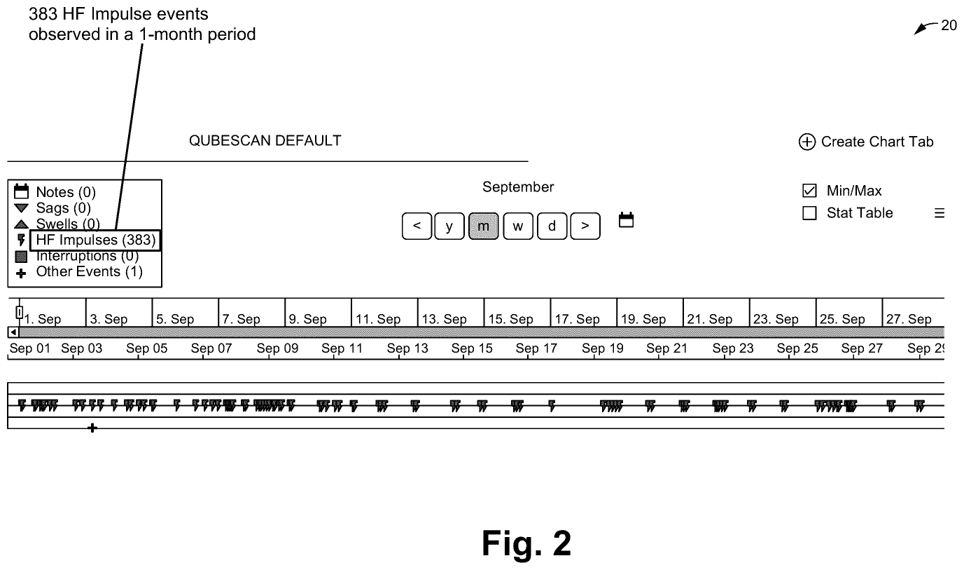

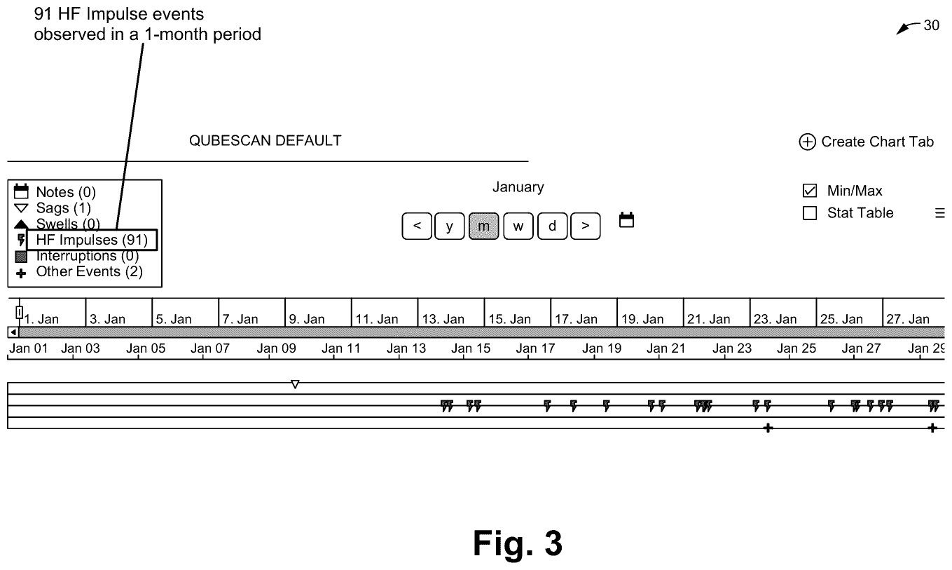

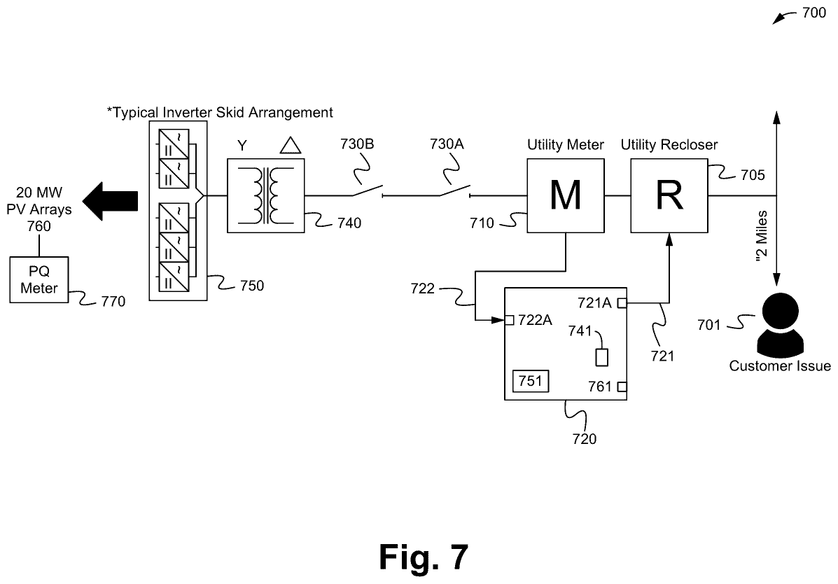

As one example, a facility deploys many advanced power quality monitors on critical infrastructure and actively utilizes a sensitive HF Impulse trigger to detect these sub-cycle events. FIG. 1 is a graph 10 of HF impulse events over time at the facility. As shown in the graph 10, a high volume of HF impulse events is observed at a measurement point that was intermittent in nature with high event concentration over a short period of time (119 HF impulse events in 1-month). In some embodiments, the measurement point is the output generated by the facility (e.g., FIG. 7, element 731) The facility ultimately experiences a catastrophic failure on a voltage transformer, resulting in a costly outage, damage to nearby infrastructure, and customer downtime. This behavior is recognized within the utility, which uses it to trigger proactive maintenance, involving proactive replacement of transformer equipment. The trigger to this proactive maintenance is based on the HF impulse events being classified as possible pre-fault conditions, and an occurrence of these events increasing to an unacceptable threshold over a short duration of time. In accordance with some embodiments, it has been determined that the higher the concentration of these events in a given time duration, the more probable it is that a serious fault condition may arise. Examples of event data that indicate fault signatures triggering proactive maintenance are shown in FIGS. 2 and 3, in graphs 20 and 30, respectively, which plot similar data as FIG. 1.

FIGS. 1, 2, and 3 are described in more detail below, in the discussion of detection of fault events.

In some embodiments, a single electrical signal on the system is monitored and compared to a fault signature, such as any combination of the magnitude (e.g., RMS magnitude and the instantaneous (Point on Wave) magnitude) and frequency of the signal over a predetermined time period. In some embodiments, a particular signature corresponds to, and is used to identify and predict, a fault of a particular component in the system or, even more precise, a particular fault in a particular component (e.g., “fault events”), each with a corresponding predicted time to failure. In some embodiments, a failure has already occurred, and the signature is used to diagnose the location and possible cause of the failure. As one example, the failure is caused by malfunctioning of an upstream component. Any maintenance may include both the affected component whose time to failure has been predicted, as well as the upstream component.

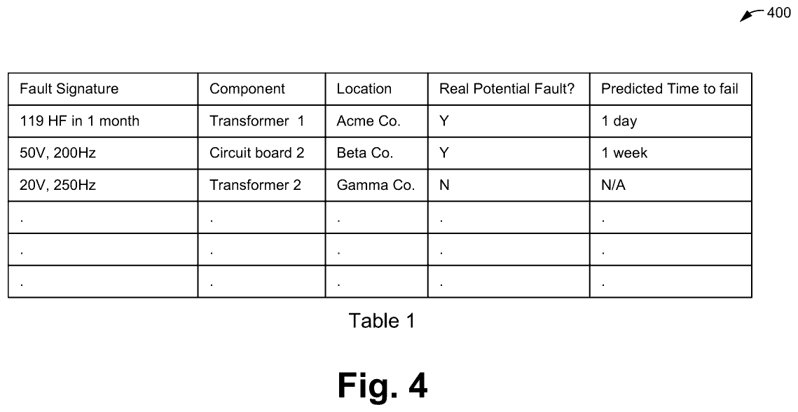

FIG. 4 is a Pre-Fault Events Table 400 correlating signatures, corresponding components, real potential fault flags/indicators (discussed below), locations of the components, and corresponding predicted times to failure, collected from historical data for different components. The data may be collected over time from a single user (e.g., vendor/service provider) or from different vendors/providers. As one example, the first row of Table 400 shows that a signature (19 HF in 1 month) for the component Transformer 1, at Acme Co., is a real potential fault (not a false positive, “Y” in column 4), predicted to fail in 1 day. It will be appreciated that the Table 400 is merely illustrative. In other embodiments, other data structures are used, other information can be added, and some can be deleted, to name only a few examples.

In some embodiments, once a failure of a component is predicted, a maintenance event is performed. In some embodiments, the maintenance event includes sending an alert to a service provider to replace the component. In some embodiments, the system generates a control signal to the an element in the system (e.g., downstream from the power source) to disconnect or power down, or otherwise isolate the component, so that the component can later be replaced or serviced.

In some embodiments, the components are simulated in dynamic models, generated and updated over a period of time. In this way, the outputs of the dynamic models (expected values) can be compared to the actual output of the components. The “fault signatures” can thus be dynamically updated to changing circumstances, such as weather (e.g., thunderstorms, high humidity, etc.). In some embodiments, the system uses artificial intelligence to “train” models to recognize and identify pre-fault signatures.

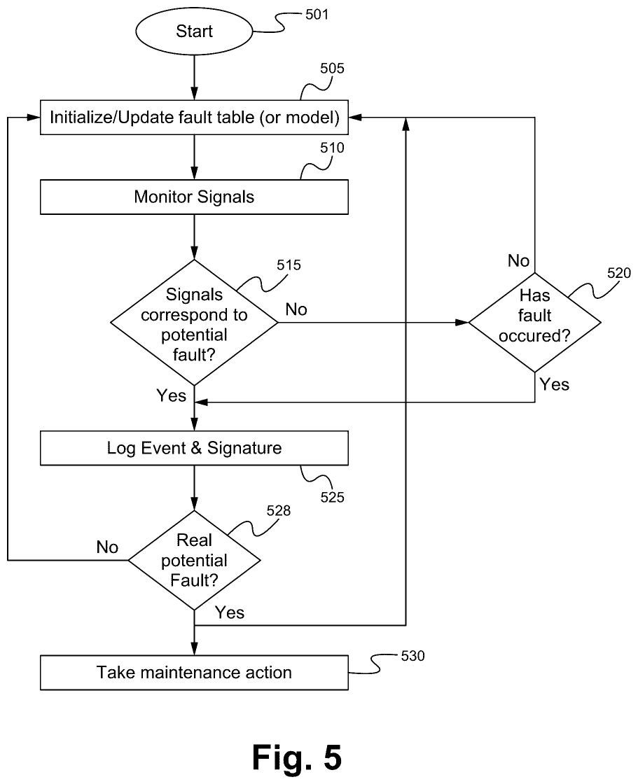

FIG. 5 is a flow chart of steps 500 of a method for monitoring for pre-fault events and taking proactive maintenance in accordance with some embodiments. In a step 501, the process starts, and in a step 505 a Table correlating signatures with components, locations of the components, real potential fault flags (e.g., Y/N), and predicted time to failure (e.g., Pre-Fault Events Table 400) is initialized. In some embodiments, the table is initialized with data collected over time, such as for corresponding components used by the current customer/user of the system or other customers/users. In some embodiments, the signature is generated from a dynamic model, updated over time, to determine whether an anomaly exists. In some embodiments, the table is initially empty and must be populated, using historical data captured associating failure events with fault signatures (e.g., voltage and current values and patterns).

Next, in a step 510, the system monitors the signals of a component. (The term “component” is used here to simplify the discussion. In operations, the system can monitor another system, components in the other system, etc.). Next, in step 515, the monitored signal is compared to a fault signature. After reading this disclosure, those skilled in the art will appreciate that a specific signal processing performance will be required to produce a minimal signal quality for monitoring and processing signatures and other signals.

If in the step 515 it is determined that the monitored signal corresponds to a fault signature (e.g., is within a predetermined range of the fault signature), the process proceeds to the step 525, where the event and signature are logged. From the step 525, the process proceeds to a step 528, where it is determined whether a real potential fault has occurred. Step 528 thus identifies “false positives,” for which maintenance actions do not have to be taken. If it is determined in the step 528 that a real potential fault has not occurred (e.g., occurrence of a false positive), the process loops back to the step 505, where, among other things, the table 400 is updated to indicate that the signature corresponds to a false positive (see, e.g., Table 4, row 3, column 4, “N”).

If, on the other hand, in the step 528, it is determined that a real potential fault has occurred, the process splits, both continuing to a step 530, where a proactive maintenance action is performed, and looping back to the step 505. In some embodiments, the maintenance action is sending an alert to a human or control program, automatically switching the predicted-to-fail component with a second component, adjusting operating values of the components (e.g., switching frequency), powering off the component (if, e.g., non critical), to name only a few examples.

If, in the step 515, it is determined that, based on the correlations in the pre-fault events table, a fault has not occurred, the process proceeds to a step 520, in which it is determined whether a fault has actually occurred (but is not included in the fault table). If a fault has not occurred, the process loops back to the step 505, where the fault table is updated if necessary. If, in the step 520, it is determined that a fault has occurred, the process continues to the step 525.

In some embodiments, the step 510 is performed on-site (e.g., collocated with the component being monitored) and the remaining steps are performed off-site, over a network, such as a cloud network. It will be appreciated that the steps 500 are merely illustrative of some embodiments. In other embodiments, some steps are added, some are deleted, the steps are performed in different orders, or any combination thereof, to name only a few possible modifications.

In some embodiments, some or all of the steps 500 are executed by one or more processors performing computer-executable instructions stored on computer-readable media. In some embodiments, some or all of the steps 500 are executed by an application specific integrated circuit (ASIC) or functionally equivalent element. In some embodiments, the step 510 is performed by a power quality monitor.

In some embodiments, for non-critical systems, a maintenance action may include displaying a warning message and then powering down the component, for example, to allow it to cool down. In other embodiments, the maintenance action may include sending a maintenance message to personnel, describing the impending fault, time to failure, maintenance/replacement suggestions, or any combination of these actions.

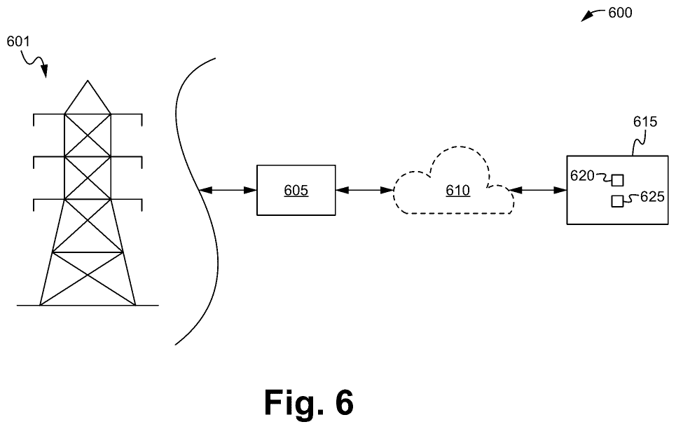

FIG. 6 is a diagram illustrating a system 600 according to some embodiments for monitoring a component (e.g., a transformer, a power grid 601, etc.). The system 600 includes a power quality monitor 605 and a processing system/module/engine 615. The power quality monitor 605 is coupled to and monitors electrical signals on the power grid 601 for fault signatures. The power monitor 605 is also coupled to a cloud network 610, which in turn couples the power quality monitor 605 to a processing system/module/engine 615. The processing engine 615 includes a first sub-module 620 and a second sub-module 625. In some embodiments, both the power quality monitor 605 and the processing engine include one or more processors and computer-readable media containing computer-executable instructions that when executed by the one or more processors perform associated steps in FIG. 5.

Referring to FIGS. 5 and 6, in some embodiments, the step 510 is executed by the power quality monitor 605 and the remaining steps are executed on the processing engine 615, such as by the first sub-module 620 and the second-submodule 625. In some embodiments, the first sub-module 620 performs the step 515 (e.g., compares signals to fault signals correlating a component failure to predicted time to failure), and the second submodule 625 performs the step 530 (e.g., generates maintenance events). In other embodiments, the steps 510, 515, 520, 525, and 528 are executed on the power quality monitor 605 or other equipment collocated with the grid 601. In still other embodiments, the execution of the steps 600 is distributed between components and locations in any manner consistent with this disclosure.

In some embodiments, a “module” includes a processor and computer-executable instructions that when executed by the processor perform steps, such as any one or more of the steps 500. In other embodiments, the term “module” refers to functionally equivalent hardware, such as application specific integrated circuits (ASICs). In some embodiments, multiple modules can share one or more processors. Those skilled in the art will recognize that the term “modules” covers other combinations of hardware and software used to implement the embodiments.

As explained above, in accordance with embodiments, fault events are associated with power quality signatures that indicate a predicted disturbance. These associations are made based on historical data, such as observed at site failures by staff or automated modules and processed by artificial intelligence, to populate Table 1 (FIG. 4), as only some examples.

In today's electrical systems, many different phenomena can degrade grid reliability. The examples below include case studies that illustrate the principles of embodiments by identifying, detecting, analyzing, and resolving problems arising from transient, harmonic, and imbalance issues on distribution grids. These examples are only illustrative. After reading this disclosure, those skilled in the art will recognize other problems that can be identified, detected, analyzed, and resolved in accordance with the principles of the invention.

Power Quality Disturbances and Examples that Illustrate Empowering a Proactive Grid

### Transients and High Frequency Impulse Applied to Pre-Fault Detection

According to “IEEE Recommended Practice for Monitoring Electric Power Quality,” IEEE Std 1159-2019, 13 Jun. 2019 (IEEE 1159-2019), there are two categories of transients: impulsive and oscillatory. Impulsive transients are unidirectional in polarity that have either a positive or a negative magnitude surge effect, whereas oscillatory transients are bidirectional and create a ringing effect in which the positive and negative polarity is rapidly fluctuating. The characteristics of both transients are sudden, momentary changes from the nominal voltage or current, and can be used to detect large magnitude transients such as lightning strikes to smaller magnitude transients such as disturbances from switching and/or the degradation of electrical assets.

In accordance with some embodiments, many factors are able to be considered when using transients to diagnose issues, including the monitoring equipment, transient thresholds, and operational influences that may be present on the source and load being monitored. Providing visibility of transient events and monitoring how frequently they occur can be important for early detection of developing faults or pre-fault conditions. The increasing occurrence of these events over time may be a sign that an issue or potential weak spot in the electrical system is emerging.

### Example 1: Case Study of High Frequency Impulse Pre-Fault Events at Primary Metering

The high frequency (HF) impulse measurement is a highly granular voltage transient event trigger that can be leveraged for predictive analysis and proactive maintenance. The HF impulse alarming condition addressed in some scenarios is a transient capture that samples the waveform up to 4 MHz (single voltage channel, 250 nano-second resolution) or 1 MHz (4 voltage channels, 1 micro-second resolution). In some embodiments, this high sampling rate is important in the detection of voltage anomalies in the electrical system as such anomalies are typically invisible to traditional metering equipment.

As one example, FIG. 1, referenced above, is a graph 10 of HF Impulse Events over time at a Utility using primary metering voltage transformers interfacing with a permanently mounted power quality monitor, which set the HF Impulse trigger to a sensitive threshold of just over two and a half times the nominal secondary voltage. Over time, the electrical behavior of the site changed, with a high volume of intermittent HF impulse events observed over a brief period (119 HF Impulses over a 1-month period). In addition to the high concentration of events, the voltage signature observed in the data is consistently low in magnitude, oscillatory in nature, and on the same phase. These events resulted in a catastrophic failure on the voltage transformer correlated with the phase the events occurred on, resulting in a costly outage, damage to nearby infrastructure, and customer downtime. In accordance with the embodiments, this recurring event pattern was recognized within the Utility, and subsequently used as a fault signature to trigger proactive replacement of the voltage transformer equipment at sites with similar behavior.

The trigger to this proactive maintenance is based on HF impulse events increasing to an unacceptable threshold over a short duration of time. The Utility considers a high concentration of these event patterns in a predetermined time duration as probable pre-fault conditions that may result in a permanently faulted condition.

### Harmonics and Compliance Reporting to Monitor Grid Health

Harmonics are generated by non-linear loads that are prevalent in today's grid, and source examples include pulse rectifiers and variable frequency drives on the load side and inverter-based resources on the generation side. The nature of harmonics involves distorting voltage and current waveforms and results in a variety of issues that can degrade electrical performance of connected equipment over time. Unchecked non-compliant harmonics accelerate the wear and tear on electrical infrastructure, thus shortening equipment lifespan and increasing replacement frequency. Some of the observable symptoms include overheating, mis-operation or failure of electrical equipment, and inefficiencies such as non-compliant power factor.

Industry standards such as “IEEE Standard for Harmonic Control in Electric Power Systems,” in IEEE Std 519-2022, 13 May 2022 (IEEE 519-2022) and IEC 61000-2-2 provide guidance for harmonics compliance. In some embodiments, the guidelines set forth in these standards are important for longevity of electrical health and include a set of compliance limits that provide a quantifiable methodology to determine if a site is in violation and at risk. This method involves running a report based on a set of voltage and current measurements over a pre-determined time (e.g., one per week, month, etc.) while utilizing a capable measurement device such as an advanced power quality monitor.

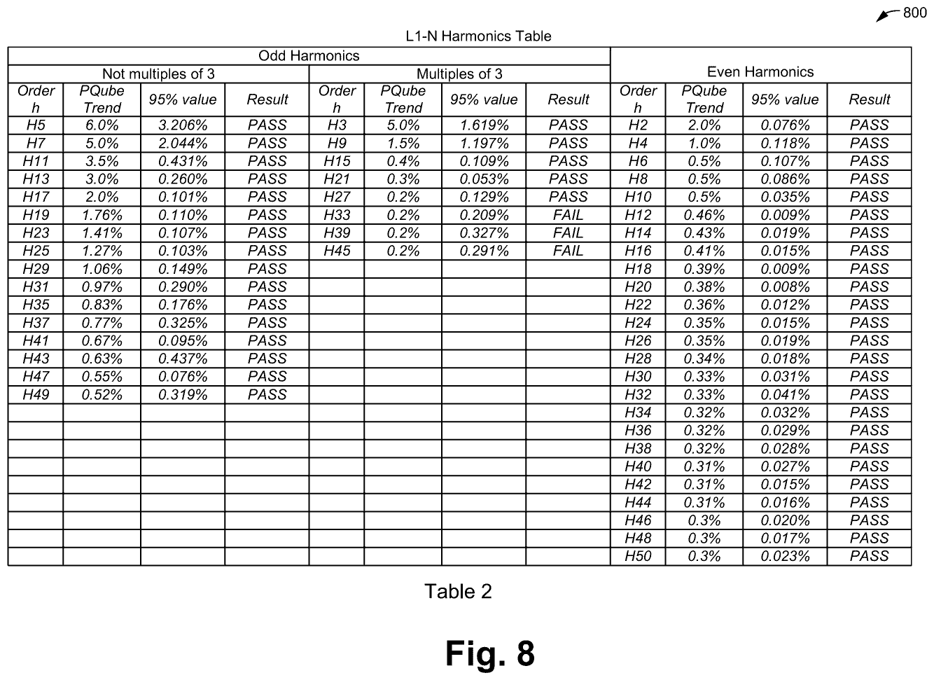

The generated report should indicate if the measurement point complies with IEEE standards or not, providing a data set of the respective harmonic orders, the measured values vs the limits, and a pass/fail status. A non-compliance condition can be used to drive proactive harmonic mitigation activity that ensures uninterrupted operation of critical infrastructure, asset reliability, and preventing interruptions in the power system. Often, the non-compliant harmonic data in this report is used to specify mitigation strategies and/or the design of harmonics mitigation equipment, such as harmonic filters, to suppress the problematic harmonics out of the system. In some embodiments, the non-compliant harmonics data corresponds to a fault signature, such as stored in Table 2 (FIG. 8) above. In some embodiments, the mitigation strategies are performed automatically, such as by inserting a harmonic filter into the transmission path. In other embodiments, the operating parameters are automatically adjusted to filter out the problematic harmonics, an adjustment that may be performed periodically as the problematic harmonics may change over time.

### Example 2: Case Study of High Order Harmonic Disturbances from a 20 MW Solar Application

A second example illustrates the principles of some embodiments. In a 20 MW utility scale solar application, a residential customer experiences malfunctioning lighting, ground fault circuit interrupters (GFCIs), and intermittent appliance issues, notably on sunny days. FIG. 7 illustrates a system 700 coupled to a Customer Site 701. The Customer Site 701 is coupled to a Utility Recloser 705, which in turn is coupled to a Utility Meter 710. The Utility Meter 710 is coupled to a first relay 730A, coupled in series to a second relay 730B, which is coupled to a transformer 740. The transformer 740 is coupled to inverters 750 to form an inverter skid arrangement. The inverters 750 are in turn coupled to a Solar Farm, 20 MW Photovoltaic Arrays 760.

In some embodiments, performance issues that occur in the system 700 are rectified by changing tunable inputs on the inverters 750. In response to the performance issues, a Power Quality Monitor 770 is coupled at a point of interconnection (POI) in the Solar Farm 760. The Power Quality Monitor 770 stores the power quality data from the Solar Farm 760 needed to immediately diagnose the issue and run an IEEE 519 harmonics compliance report. A temporary Power Quality Monitor 720 is also installed at the Customer Site 701 (e.g., a residence) to correlate the findings.

The Power Quality Monitor 720 includes a processor 741, computer-readable media 751 containing computer-executable instructions for execution by the processor 741, a port 721A for coupling the Power Quality Monitor 720 over a signal line 721 to the Utility Recloser 705, a port 722A for coupling the Power Quality Monitor 720 to the Utility Meter 710 over a signal line 722, and a communications port 761 for communications with remote systems (e.g., FIG. 6, element 615) over the Internet or Cloud Network, to name a few examples. In some embodiments, the Power Quality Monitor 770 includes elements/functionality similar to that of the Power Quality Monitor 720.

In some embodiments, the Power Quality Monitor 720 monitors signals transmitted from the Solar Farm 760 at the Utility Meter 710 over the line 722. In some embodiments, in response to the detection of pre-fault events over the line 722, the Power Quality Monitor 720 generates control signals over the line 721 to trigger the maintenance event of opening the Utility Recloser 705, thereby disconnecting the Customer Site 701 from the Transformer 740. In some embodiments, the computer-executable instructions stored in the computer-readable media 751 and executed by the processor 741 perform one or more of the steps 500 in FIG. 5. In other embodiments, some of the steps 500 can be performed at a location remote from the Power Quality Monitor 720. After reading this disclosure, those skilled in the art will recognize other maintenance events that can be performed in accordance with the embodiments.

In this example, during the investigation, it was noted that the long-term flicker (Pₗₜ) and short-term flicker (Pₛₜ) detected by Power Quality Monitor 720 on the line 722 were complying with the levels specified by IEEE Standard for Measurement and Limits of Voltage Fluctuations and Associated Light Flicker,” in IEEE Std 1453-2022, 16 Jun. 2022 (IEEE 1453-2022), and there were no voltage variation disturbances such as voltage sags. When observing the IEEE 519 harmonics report, there were no violations associated with higher order harmonics; however, the IEC 61000-2-2 report indicated non-compliant harmonic limits observed at odd harmonic orders H33, H39, and H45 (1.98 kHz to 2.7 kHz), as shown in Table 2 in FIG. 8, showing a Voltage Harmonics Compliance Chart. The Chart, an L1-N Harmonics Table, stores Odd and Even Harmonics, the Odd Harmonics including “Not Multiples of 3” and “Multiples of 3.” For each type of Harmonic, the Table shows Order h, PQube Trend, 95% Value, and Result (Pass/Fail).

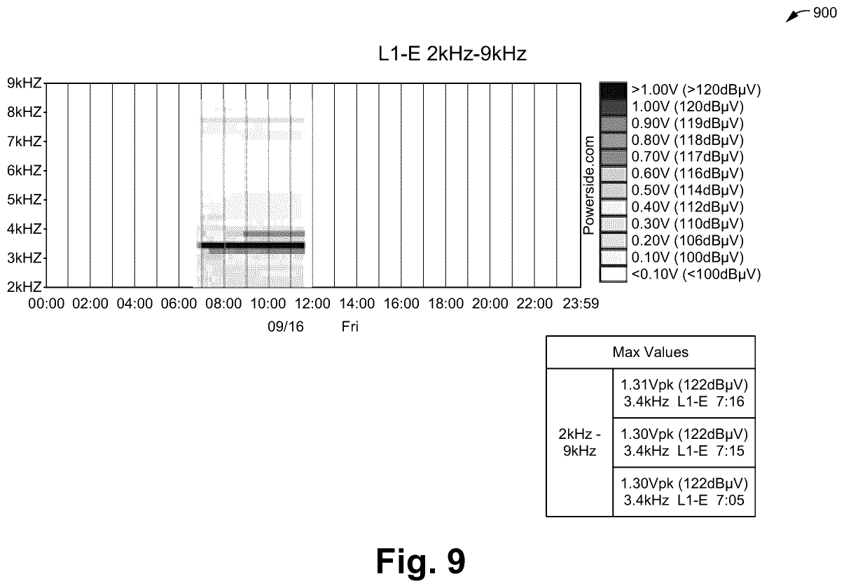

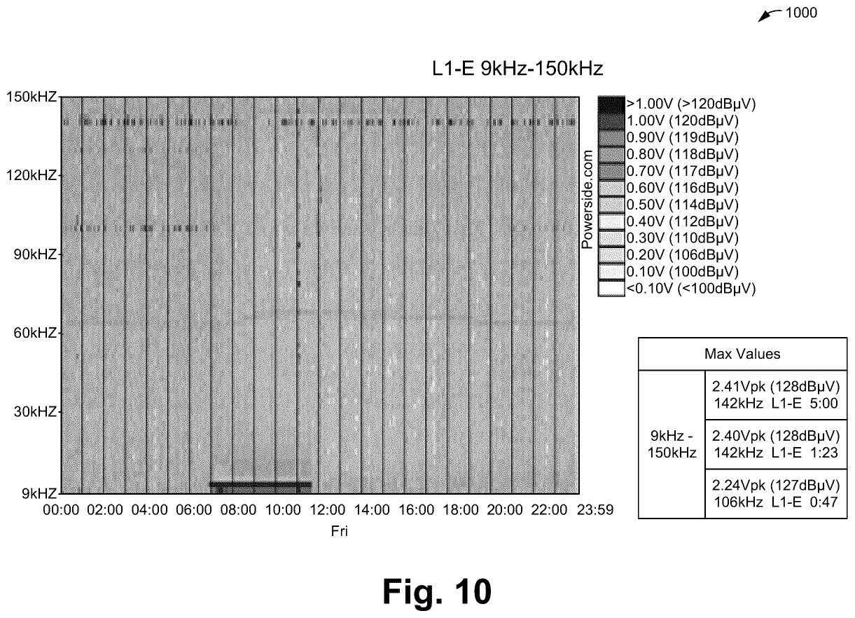

Additionally, as shown in FIGS. 9 and 10, the conducted emissions noise in the 2 to 150 kHz range (also known as supraharmonics) were observed in the “Heat Map” graphs 900 and 1000, respectively, generated by the Power Quality Monitor 770 (FIG. 7), and found to have a high concentration of voltage distortion at 3.4 kHz in the 2 to 9 Khz spectrum (200 Hz bin resolution) and the 10 kHz, 12 kHz, and 142 kHz bands in the 9 to 150 kHz spectrum (2 kHz bin resolution). The conducted emissions values observed are frequency values beyond what the industry standards for harmonics have compliance limits for (up to the 50th harmonic or 3 kHz). The 3.4 kHz, 10 kHz, and 12 kHz noise observed was steady state until the solar was isolated, while the 142 kHz appears to be an intermittent distortion that occurred throughout the day, after solar was isolated from the feeder. The steady state high frequency distortion observed was determined to be due to the inverters 750 utilized at the 20 MW Solar Farm 760 and suspected to be multiples of the switching frequency of the inverter 750. This switching frequency is integral to inverter operation and generated during the process of inverting the Vdc signal into a 60 Hz Vac sine wave. The Solar Farm 760 was isolated to troubleshoot the issue, which can be observed when the high frequency distortion abruptly stopped in the conducted emissions graphs, right before 12:00. Upon isolating the solar from the problem site, the symptoms from the problematic harmonic distortion subsided.

In some embodiments, the Heat Maps 900 and 1000 are digitized and translated into fault signatures. In this way, heat patterns can also be used to identify fault signatures in accordance with the embodiments. In some embodiments, heat maps can represent high distortion, which can be a symptom of equipment issues, resonance, etc.

To address the issue by taking preventative action (e.g., maintenance events), the inverter 750 was adjusted by pulse shifting the switching frequency at the problematic bands. This in turn, cancelled out the higher magnitudes of distortion that caused the symptoms observed. In accordance with embodiments, the pulse shifting of the switching frequency is performed manually, on-site. In other embodiments, the inverter pulse shifting is adjusted by the manufacturer or other third party off-site. In other embodiments, the pulse shifting is triggered remotely.

In some embodiments, a Utility permanently mounts power quality monitoring at all Utility scale solar installations and runs combined IEEE 519 and power quality compliance reports during the commissioning process. This reporting is taken in two steps: at pre-generation to validate voltage compliance before the Point of Interconnection (POI) is closed, and at post generation to validate voltage and current compliance after the POI is closed. In some embodiments, the POI is a Utility Recloser, such as the Utility Recloser 705 in FIG. 7. In some embodiments, IEEE 519 reports are automatically generated monthly at all sites that have the most recent standard of power quality monitoring installed. These efforts provide the utility with tools to proactively address power quality issues and to continually monitor compliance under the continually changing load conditions, particularly those resulting from electric vehicles, data centers, and other inverter-based technology.

### Imbalance

In some embodiments, detecting imbalance issues is critical to ensuring reliable operations in the grid, particularly to operations utilizing motor driven systems. Imbalance in electrical systems refers to an uneven distribution of voltage or current among the phases, which can lead to a variety of issues such as inefficiencies, premature failure of equipment, and safety hazards. Increasing visibility on this measurement early on can help mitigate the resulting electrical stresses and equipment degradation by scheduling corrective actions before an interruption or safety hazard occurs.

Imbalance is the ratio of negative sequence to positive sequence component magnitudes in voltage or current, per “IEEE Recommended Practice for Monitoring Electric Power Quality,” IEEE Std 1159-2019, 13 Jun. 2019 (“IEEE 1159-2019”). This standard provides reference values on typical characteristics for voltage and current imbalance. Measurements exceeding those typical values may be harmful to the electrical systems and equipment assets. Real-time alerts assist in getting ahead of the issue to diagnose and proactively plan for mitigation.

### Example 3: Case Study of Imbalance at Net Metering Application

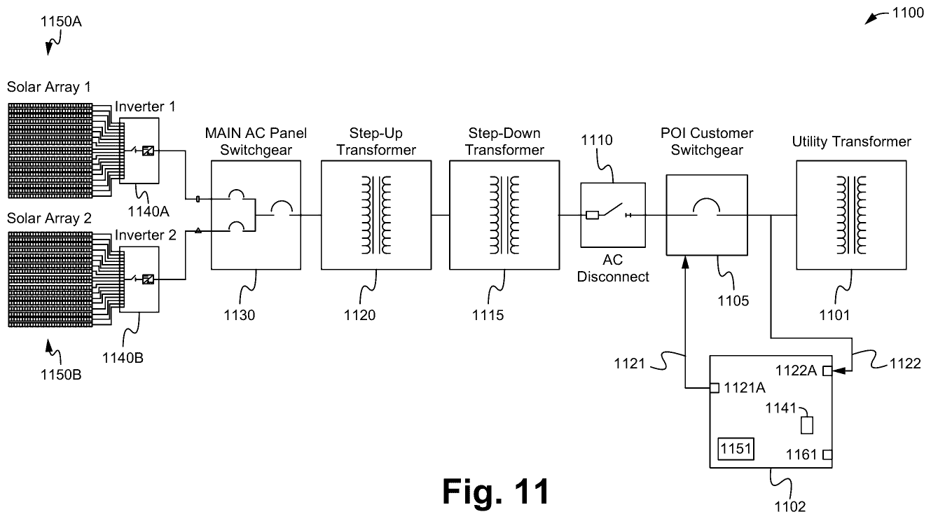

As one example, a net metering site customer with 250 kW of ground mounted solar arrays reports power quality issues to the local Utility. FIG. 11 shows a system 1100 used to illustrate imbalance, identified in accordance with embodiments. The system 1100 includes a Utility Transformer 1101 coupled to a POI Customer Switchgear 1105, in turn coupled to an AC Disconnect 11010. The AC Disconnect 1110 is coupled to a Grounded Wye-Delta Step-Down Transformer 1115, which is coupled to a Grounded Wye-Delta Step-Up transformer 1120 (included due to the long cable run distance between solar and the POI), which is coupled to a Main AC Panel Switchgear 1130. The Main AC Panel Switchgear 1130 is coupled to a first inverter 1140A in parallel with a second inverter 1140B, which are coupled to a first Solar Array 1150A and a second Solar Array 1150B, respectively. Upon initial inspection of the site, the insulation of the neutral cable in the Utility Transformer 1101 was observed to have melted away from the conductor due to excessive heat. A Power Quality Monitor 1102 was coupled to the output of the POI Customer Switchgear 1105 to investigate the issue and a significant amount of zero sequence current was observed, with approximately 430A of current flow through the transformer neutral.

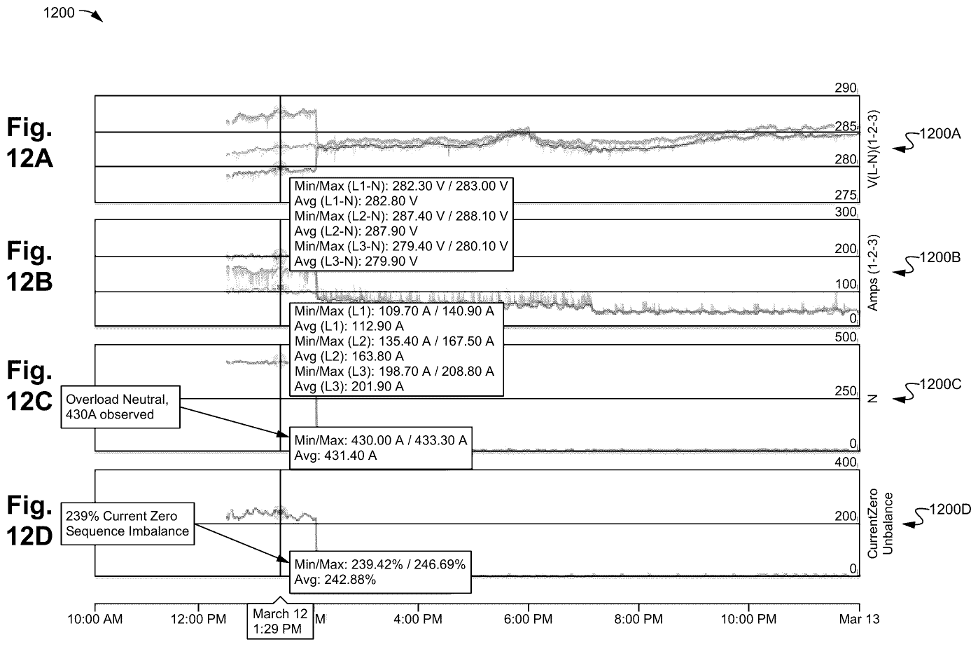

The Power Quality Monitor 1102 includes computer-readable media 1151 and a processor 1141, with similar functionality as the computer-readable media 751 and processor 741, respectively, as the Power Quality Monitor 720 in FIG. 7. The Power Quality Monitor1102 is coupled to the output of the POI Customer Switchgear 1105 over the signal line 1122 and to the control input of the Custom Switchgear 1105 over the signal line 1121. When observing the phasors behavior, the current phase angles measured were in a state of significant imbalance, which was also reflected in the zero-sequence current as shown in the graphs in FIG. 12A-D, plotting Voltage, Current, Neutral, and Current Zero Unbalance over time. This imbalance created the overheating and melted condition observed on the secondary cable.

Depending on the position of the delta transformation, it can result in temporary overvoltage that can damage equipment or become a zero-sequence path. Grounding banks are zero sequence sources that can lead to other factors that impact grid operation such as incorrect meter readings, protective relays, and have the potential for ferroresonance. The transformation in question created a grounding bank, resulting in the observed imbalance condition and zero sequence source.

After the site analysis and recommendations, all secondary cables to the POI Customer Switchgear 1105 were replaced due to extensive damage to the neutral and adjacent conductors. A dissolved gas analysis test was performed on the Utility Transformer 1101 and indicated acceptable compliance levels. The analysis showed the Utility Transformer 1101 was exposed to sustained electrical stress that could have resulted in degradation of useful life. These factors, combined with safety considerations (the device was located near pedestrian traffic), triggered a maintenance event, prompting proactive replacement of the Utility Transformer 1101. The Delta-Wye Step-Up Transformer 1220 and Delta-Wye Step-Down Transformer 1115 were both replaced with Grounded Wye-Grounded Wye transformer configurations, per the Utility recommendations.

In this example, the fault signature corresponds to the detection of the zero sequence current, with the component failure of the neutral cable in the Utility Transformer 1101. In some embodiments, the Power Quality Monitor 1102 generates an output signal on line 1121, coupled to the POI Customer Switchgear 1105. When the Power Quality Monitor 1102 detects a pre-fault signature over the line 1122, the signal generated on the line 1121 opens the POI Customer Switchgear 1105, automatically disconnecting the transmission to the Utility Transformer 1101. After reading this disclosure, those skilled in the art will recognize other maintenance events that can be employed based on the pre-fault component or the upstream equipment. For example, the signal generated on the line 1121 can be coupled to the AC Disconnect 1110 to disconnect transmission to the Utility Transformer 1101.

In operation, grid components are monitored. If the grid output matches (e.g., is within a pre-determined limit of) fault signatures, preventive action (e.g., a maintenance event) is taken, such as by manually or automatically disconnecting or powering off a malfunctioning or predicted-to-malfunction component. In some embodiments, the comparisons (e.g., matchings) are performed locally, on-site. In other embodiments, the monitored signals are transmitted, such as over the Internet or Cloud, off-site, for remote processing. In some embodiments, components can be manually or automatically replaced or tuned/adjusted. In some embodiments, the output is compared to standard values, such as IEEE performance values, and a fault predicted if the output differs from the IEEE standard values by at least a predetermined amount. In some embodiments, the systems generate reports correlating pre-fault signatures with components failures based on historical data.

The embodiments above refer to IEEE and European Norm standards. These standards are included merely for illustration and are not intended to be limiting. It will be appreciated that when the embodiments are implemented in other countries, comparisons, fault signatures, fault events, etc., will be determined according to the standards followed in those countries.

In operation, some embodiments work at the “grid edge” to monitor for pre-fault signatures to better predict and proactively react to possible system/component failures. While some of the embodiments describe monitoring/maintaining grids, transformers, and other components, it will be appreciated that the principles of the embodiments can be applied to renewables, high-mega watt consumption data centers, solar farms, micro-grids, battery energy storage devices, and the components of each, to name only a few examples.

After reading this disclosure, those skilled in the art will recognize other possible modifications and applications consistent with this disclosure. It will be readily apparent to one skilled in the art that various other modifications may be made to the embodiments without departing from the spirit and scope of the invention as defined by the appended claims.

1. A method of responding to pre-fault events in an electrical system comprising:
monitoring electrical signals generated by the system;
comparing the electrical signals to a fault signature;
in response to the comparison, triggering a maintenance event.

2. The method of claim 1, wherein the electrical signals correspond to the fault signature.

3. The method of claim 2, wherein the fault signature comprises a magnitude of a signal, a frequency of the signal, a phase angle of the signal, patterns of the magnitude and frequencies, a time period over which the signals occur, or any combination thereof.

4. The method of claim 2, further comprising generating a database correlating fault signatures with components and predicted times to failure.

5. The method of claim 4, wherein the correlations in the database are generated using artificial intelligence, dynamic modeling, machine learning, or any combination thereof.

6. The method of claim 1, wherein the maintenance event comprises automatically disconnecting or powering down a component associated with a fault signature.

7. The method of claim 1, wherein the maintenance event comprises automatically powering down the system.

8. The method of claim 1, wherein the maintenance event comprises automatically adjusting an operating value of a component associated with the fault signature.

9. The method of claim 1, wherein the maintenance event comprises sending an alert to a predetermined party.

10. The method of claim 1, wherein the signature corresponds to a high-frequency impulse within a predetermined range.

11. The method of claim 1, wherein the monitoring is performed using a power analyzer.

12. The method of claim 1, wherein monitoring electrical signals comprises sampling the signals at 1 MHz or higher frequencies.

13. A system for maintaining a power source comprising:
an analyzer to analyze one or more signals of the power source;
a comparator for comparing the signal to a fault signature correlating a failure of
a component of the power source to a predicted time to failure; and
a maintenance module for generating a maintenance event when the signals correspond to the fault signature.

14. The system of claim 13, wherein the analyzer is coupled to the comparator, the maintenance module, or both over a network.

15. The system of claim 14, wherein the network comprises a cloud network.

16. The system of claim 13, wherein the maintenance module generates the maintenance event in real time.

17. The system of claim 13, wherein the analyzer comprises a power quality monitor.

18. The system of claim 13, where the system is included in a power quality monitor.
